(19) United States
(12) Patent Application Publication
(10) Pub. No.: US 2013/0321063 A1
(43) Pub. Date: Dec. 5, 2013

(54) MOS SWITCH

(71) Applicant: Carmine Cozzolino, Encinitas, CA (US)

(72) Inventor: Carmine Cozzolino, Encinitas, CA (US)

(73) Assignee: Fairchild Semiconductor Corporation, San Jose, CA (US)

(21) Appl. No.: 13/485,461

(22) Filed: May 31, 2012

(51) Int. Cl. H03K 17/693

(52) U.S. Cl. 327/437

(57) ABSTRACT

This document discusses, among other things, a switch circuit including a switch having a low-impedance state configured to couple a first node to a second node and a high-impedance state configured to isolate the first node from the second node. The switch circuit can include an arbiter circuit configured to receive a source voltage and an input signal, to provide, at an output, the higher voltage of the source voltage and the input signal, and to isolate the input signal form ground when the input signal has a lower voltage than the source voltage.

### BACKGROUND

An analog switch can be configured to couple an analog signal to, or to isolate an analog signal from, a circuit path. In contrast, a digital switch can be configured to change an output state in response to a received input, but does not pass a received signal from an input to an output.

### OVERVIEW

This document discusses, among other things, a switch circuit including a switch having a low-impedance state configured to couple a first node to a second node and a high-impedance state configured to isolate the first node from the second node. The switch circuit can include an arbiter circuit configured to receive a source voltage and an input signal, to provide, at an output, the higher voltage of the source voltage and the input signal, and to isolate the input signal form ground when the input signal has a lower voltage than the source voltage.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example switch circuit including a switch.

FIG. 2 illustrates generally an example switch circuit including a switch and an arbiter circuit.

FIG. 3 illustrates generally example first and second input signals applied to the switches illustrated in the examples of FIGS. 1 and 2.

### DETAILED DESCRIPTION

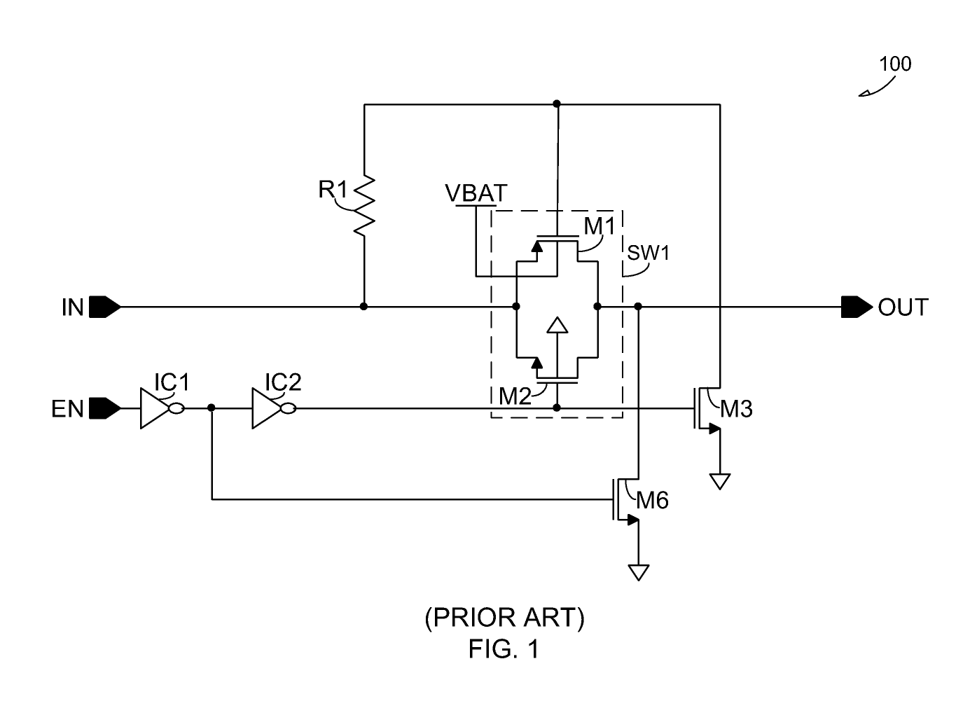

FIG. 1 illustrates generally an example switch circuit 100 including a switch SW1 (e.g., an analog switch) configured to couple a first node (e.g., an input node (IN)) to a second node (e.g., an output node (OUT)) in a first state, such as a low-impedance or “ON” state, and to isolate the first node from the second node in a second state, such as a high-impedance or “OFF” state.

The switch SW1 can include a first transistor M1 and a second transistor M2, each having a gate, a source, and a drain. In an example, the first transistor M1 can include a p-channel transistor and the second transistor M2 can include an n-channel transistor, the sources of the first and second transistors M1, M2 can be coupled to the first node, and the drains of the first and second transistors M1, M2 can be coupled to the second node. In an example, a bulk of the first transistor M1 can be coupled to a source voltage, such as a battery voltage (VBAT), and a bulk of the second transistor M2 can be coupled to ground.

In an example, the switch circuit 100 can be configured to receive an enable signal, for example, at an enable input EN. The gate of the second transistor M2 can be configured to receive the enable signal. In an example, the switch circuit 100 can further include a third transistor M3 (e.g., an n-channel transistor) having a gate, a source, and a drain, and the gate of the third transistor M3 can be configured to receive a representation of the enable signal and to selectively couple the gate of the first transistor M1 to ground using the representation of the enable signal.

In an example, the switch circuit 100 can include first and second inverters IC1, IC2 configured to receive, and in certain examples, buffer the enable signal and provide an inverse enable signal. The switch circuit 100 can include a sixth transistor M6 (e.g., an n-channel transistor) configured to receive a representation of the enable signal and to selectively couple the second node to ground using the representation of the enable signal.

To keep the switch SW1 in the high-impedance state when an input signal at the first node is greater than the source voltage (e.g., VBAT), the switch circuit 100 can include a resistor R1 configured to couple the first node to the gate of the first transistor M1. However, when the switch is in the low-impedance state, the resistor R1 can provide a direct current (DC) path from the first or second nodes, and thus, the input signal at the first node or an output signal at the second node, to ground, which can cause a common mode voltage shift to the input or output signal if the switch SW1 is driving a fully differential amplifier, such as in a speaker drive application. The common mode voltage shift can limit the input signal swing, and consequently can limit an available power, such as to the speaker load in speaker drive applications.

The present inventors have recognized, among other things, systems and methods to isolate the input signal from ground when the input signal has a lower voltage than the source voltage.

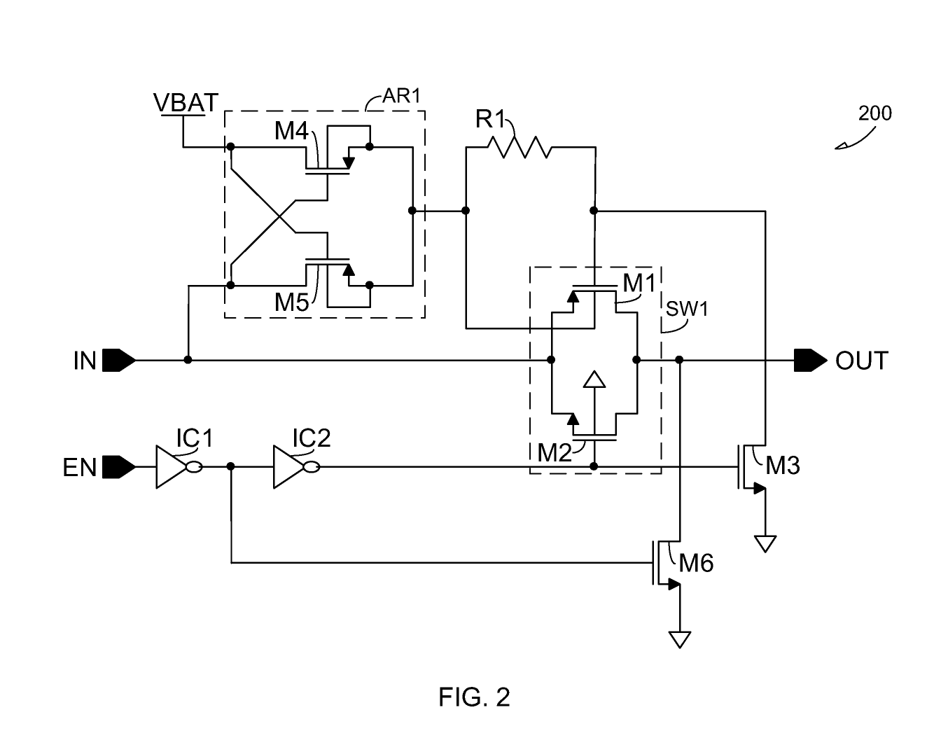

FIG. 2 illustrates generally an example switch circuit 200 including a switch SW1 (e.g., an analog switch) configured to couple a first node (e.g., an input node (IN)) to a second node (e.g., an output node (OUT)) in a first state, such as a low-impedance or “ON” state, and to isolate the first node from the second node in a second state, such as a high-impedance or “OFF” state.

The switch circuit 200 further includes an arbiter circuit AR1 configured to receive a source voltage, such as a battery voltage (VBAT), and an input signal, such as an input signal at the first node, and to provide, at an output, the higher voltage of the source voltage and the input signal. In an example, the arbiter circuit AR1 can be configured to isolate the input signal from ground when the switch SW1 is in the low-impedance state and the input signal has a lower voltage than the source voltage.

In an example, the arbiter circuit AR1 can include fourth and fifth transistors M4, M5, each having a gate, a drain, and a source. In certain examples, the fourth and fifth transistors M4, M5 can include p-channel transistors, the drain of the fourth transistor M4 and the gate of the fifth transistor M5 can be configured to receive the source voltage, the gate of the fourth transistor M4 and the drain of the fifth transistor M5 can be configured to receive the input signal, and the source of the fourth transistor M4 can be coupled to the source of the fifth transistor M5 and can be configured to provide, as the output of the arbiter circuit AR1, the higher voltage of the source voltage and the input signal.

The switch circuit SW1 can include a first transistor M1. In an example, the first transistor M1 can include a p-channel transistor having a gate, a drain, and a source, the source of the first transistor M1 can be coupled to the first node, and the drain of the first transistor M1 can be coupled to the second node. A bulk connection of the first transistor M1 can be coupled to the output of the arbiter circuit AR1, and the switch circuit 200 can include a resistor R1 configured to couple the output of the arbiter circuit AR1 to the gate of the first transistor M1.

Accordingly, when the switch SW1 is in a high-impedance state, the greater of the source voltage (e.g., VBAT) or the input signal can be provided to the gate of the first transistor M1 (and the body of the first transistor M1), keeping the switch SW1 in the high-impedance state, even when the input signal has a higher voltage than the source voltage. Further, in contrast to the example illustrated in FIG. 1, when the switch SW1 is in a low-impedance state and the input signal has a lower voltage than the source voltage (e.g., VBAT), there is no direct current (DC) path to ground through the resistor R1, which can prevent a common mode voltage shift at the input signal if the switch SW1 is driving a fully differential amplifier.

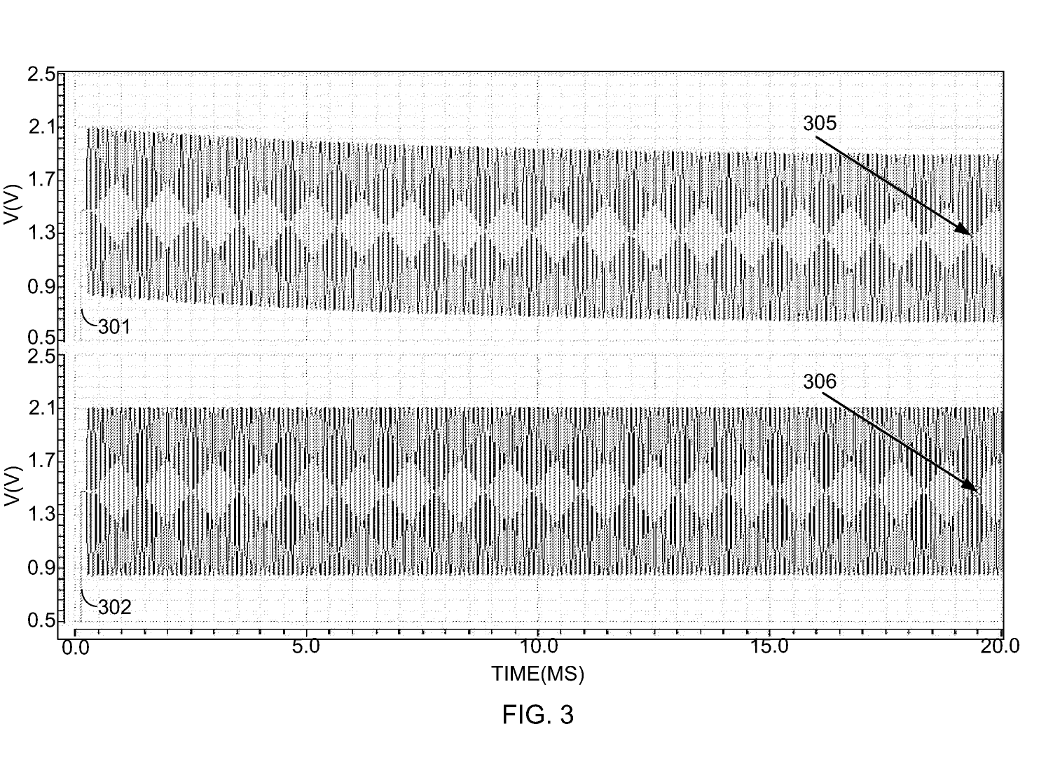

FIG. 3 illustrates generally example first and second input signals 301, 302 applied to the switches illustrated in the examples of FIGS. 1 and 2, respectively. The input signal 301 illustrates an analog signal applied to the switch circuit 100 of the example of FIG. 1, and the input signal 302 illustrates the same analog signal applied to the switch circuit 200 of the example of FIG. 2. In an example, the first input signal 301 illustrates, at 305, a common mode voltage of 1.261635V, shifting from an estimated initial voltage of 1.475V. In contrast, the second input signal 302 illustrates, at 305, a common mode voltage of 1.475945V with little shift from the initial voltage level.

In an example, one or more of the transistors disclosed herein can include a field-effect transistor (FET), a metal-oxide-field-effect transistor (MOSFET), or one or more other type of transistor.

### Additional Notes and Examples

In Example 1, a system includes a switch having a low-impedance state configured to couple a first node to a second node and a high-impedance state configured to isolate the first node from the second node and an arbiter circuit configured to receive a source voltage and an input signal and to provide at an output the higher voltage of the source voltage and the input signal, wherein the arbiter circuit is configured to isolate the input signal from ground when the input signal has a lower voltage than the source voltage.

In Example 2, the arbiter circuit of Example 1 is optionally configured to isolate the input signal from ground when the switch is in the low-impedance state.

In Example 3, the switch of any one or more of Examples 1-2 optionally includes a first transistor and a second transistor, each having a low-impedance state configured to couple the first node to the second node and a high-impedance state configured to isolate the first node from the second node.

In Example 4, the first transistor of any one or more of Examples 1-3 optionally includes a p-channel transistor having a gate, a source, and a drain, wherein the first node optionally includes the source of the first transistor, and the second transistor of any one or more of Examples 1-3 optionally includes an n-channel transistor having a gate, a source, and a drain, wherein the first node optionally includes the source of the second transistor.

In Example 5, any one or more of Examples 1-4 optionally includes a third transistor configured to receive an enable signal and to selectively couple the gate of the first transistor to ground using the enable signal.

In Example 6, any one or more of Examples 1-5 optionally includes a resistor configured to couple the output of the arbiter circuit to the gate of the first transistor, wherein a bulk of the first transistor is optionally coupled to the output of the arbiter circuit.

In Example 7, the second node of any one or more of Examples 1-6 optionally includes the drain of the first transistor and the drain of the second transistor.

In Example 8, the arbiter circuit of any one or more of Examples 1-7 optionally includes a fourth transistor and a fifth transistor, each having a gate, a source, and a drain, wherein the drain of the fourth transistor is optionally configured to receive the source voltage, wherein the gate of the fourth transistor is optionally configured to receive the input signal, wherein the drain of the fifth transistor is optionally configured to receive the input signal, wherein the gate of the fifth transistor is optionally configured to receive the source voltage, and wherein the source of the fourth transistor is optionally coupled to the source of the fifth transistor and is optionally configured to provide the higher voltage of the source voltage and the input signal.

In Example 9, any one or more of Examples 1-8 optionally includes a resistor configured to couple the output of the arbiter circuit to a control node of the switch.

In Example 10, any one or more of Examples 1-9 optionally includes a third transistor coupled to the control node of the switch and configured to receive an enable signal and to control the switch using the enable signal.

In Example 11, a method includes selectively coupling a first node to a second node using a switch in a low-impedance state and isolating the first node from the second node using the switch in a high-impedance state; receiving a source voltage and an input voltage at an arbiter circuit; providing, at an output of the arbiter circuit, the higher voltage of the source voltage and the input signal; and isolating, using the output of the arbiter circuit, the input signal from ground when the input signal has a lower voltage than the source voltage.

In Example 12, any one or more of Examples 1-11 optionally includes isolating, using the output of the arbiter circuit, the input signal from ground when the switch is in the low-impedance state.

In Example 13, the switch of any one or more of Examples 1-12 optionally includes a first transistor and a second transistor, wherein the selective coupling the first node to the second node optionally includes using the first and second transistors in a low-impedance state, and wherein the selectively isolating the first node from the second node optionally includes using the first and second transistors in a high-impedance state.

In Example 14, the first transistor of any one or more of Examples 1-13 optionally includes a p-channel transistor having a gate, a source, and a drain, and wherein the first node includes the source of the first transistor, and wherein the second transistor includes an n-channel transistor having a gate, a source, and a drain, and wherein the first node includes the source of the second transistor.

In Example 15, any one or more of Examples 1-14 optionally includes receiving an enable signal using a gate of a third transistor; and selectively coupling the gate of the first transistor to ground using the enable signal.

In Example 16, the output of the arbiter circuit of any one or more of Examples 1-15 is optionally coupled to the gate of the first transistor using a resistor, and wherein a bulk of the first transistor is coupled to the output of the arbiter circuit.

In Example 17, the second node of any one or more of Examples 1-16 optionally includes the drain of the first transistor and the drain of the second transistor.

In Example 18, the arbiter circuit of any one or more of Examples 1-17 optionally includes a fourth transistor and a fifth transistor, each having a gate, a source, and a drain, wherein the receiving the source voltage optionally includes using the drain of the fourth transistor and the gate of the fifth transistor, wherein the receiving the input signal optionally includes using the gate of the fourth transistor and the drain of the fifth transistor, and wherein the providing the higher voltage of the source voltage and the input signal optionally includes using the source of the fourth transistor and the source of the fifth transistor.

In Example 19, the output of the arbiter circuit of any one or more of Examples 1-18 is optionally coupled to a control node of the switch using a resistor.

In Example 20, any one or more of Examples 1-19 optionally includes a third transistor coupled to the control node of the switch and configured to receive an enable signal and to control the switch using the enable signal.

In Example 21, any one or more of Examples 1-20 optionally includes a switch having a low-impedance state configured to couple a first node to a second node and a high-impedance state configured to isolate the first node from the second node. The switch can include a first transistor and a second transistor, each having a low-impedance state configured to couple the first node to the second node and a high-impedance state configured to isolate the first node from the second node, wherein the first transistor includes a p-channel transistor having a gate, a source, and a drain, and the second transistor includes an n-channel transistor having a gate, a source, and a drain, wherein the first node includes the source of the first transistor and the source of the second transistor, and wherein the second node includes the drain of the first transistor and the drain of the second transistor. Example 21 optionally includes a third transistor configured to receive an enable signal and to selectively couple the gate of the first transistor to ground using the enable signal and an arbiter circuit configured to receive a source voltage and an input signal and to provide at an output the higher voltage of the source voltage and the input signal. The arbiter circuit optionally includes a fourth transistor and a fifth transistor, each having a gate, a source, and a drain, wherein the drain of the fourth transistor is configured to receive the source voltage and the gate of the fourth transistor is configured to receive the input signal, wherein the drain of the fifth transistor is configured to receive the input signal and the gate of the fifth transistor is configured to receive the source voltage, and wherein the source of the fourth transistor is coupled to the source of the fifth transistor and configured to provide the higher voltage of the source voltage and the input signal. Example 21 further optionally includes a resistor configured to couple the output of the arbiter circuit to the gate of the first transistor. A bulk of the first transistor is optionally coupled to the output of the arbiter circuit, and the arbiter circuit is optionally configured to isolate the input signal from ground when the input signal has a lower voltage than the source voltage and when the switch is in the low-impedance state.

In Example 22, a system can include, or can optionally be combined with any portion or combination of any portions of any one or more of Examples 1-21 to include, subject matter that can include means for performing any one or more of the functions of Examples 1-21, or a machine-readable medium including instructions that, when performed by a machine, cause the machine to perform any one or more of the functions of Examples 1-21.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A system comprising:
a switch having a low-impedance state configured to couple a first node to a second node and a high-impedance state configured to isolate the first node from the second node;
an arbiter circuit configured to receive a source voltage and an input signal and to provide at an output the higher voltage of the source voltage and the input signal; and
a ground path between a control input of the switch and circuit ground,
wherein the arbiter circuit is configured to isolate the input signal from the ground path when the input signal has a lower voltage than the source voltage.

2. The system of claim 1, wherein the arbiter circuit is configured to isolate the input signal from the ground path when the switch is in the low-impedance state.

3. The system of claim 1, wherein the switch includes a first transistor and a second transistor, each having a low-impedance state configured to couple the first node to the second node and a high-impedance state configured to isolate the first node from the second node.

4. The system of claim 3,
wherein the first transistor includes a p-channel transistor having a gate, a source, and a drain, and wherein the first node includes the source of the first transistor, and
wherein the second transistor includes an n-channel transistor having a gate, a source, and a drain, and wherein the first node includes the source of the second transistor.

5. The system of claim 4, including a third transistor configured to receive an enable signal and to selectively couple the gate of the first transistor to ground using the enable signal.

6. The system of claim 4, including a resistor configured to couple the output of the arbiter circuit to the gate of the first transistor,
wherein a bulk of the first transistor is coupled to the output of the arbiter circuit.

7. The system of claim 4, wherein the second node includes the drain of the first transistor and the drain of the second transistor.

8. The system of claim 1,
wherein the arbiter circuit includes a fourth transistor and a fifth transistor, each having a gate, a source, and a drain,
wherein the drain of the fourth transistor is configured to receive the source voltage,
wherein the gate of the fourth transistor is configured to receive the input signal,
wherein the drain of the fifth transistor is configured to receive the input signal,
wherein the gate of the fifth transistor is configured to receive the source voltage, and
wherein the source of the fourth transistor is coupled to the source of the fifth transistor and configured to provide the higher voltage of the source voltage and the input signal.

9. The system of claim 1, including a resistor configured to couple the output of the arbiter circuit to a control node of the switch.

10. The system of claim 9, including a third transistor coupled to the control node of the switch and configured to receive an enable signal and to control the switch using the enable signal.

11. A method comprising:
selectively coupling a first node to a second node using a switch in a low-impedance state and isolating the first node from the second node using the switch in a high-impedance state;
receiving a source voltage and an input voltage at an arbiter circuit;
providing, at an output of the arbiter circuit, the higher voltage of the source voltage and the input signal; and
isolating, using the output of the arbiter circuit, the input signal from a ground path between a control input of the switch and circuit ground when the input signal has a lower voltage than the source voltage.

12. The method of claim 11, including isolating, using the output of the arbiter circuit, the input signal from the ground path when the switch is in the low-impedance state.

13. The method of claim 11,
wherein the switch includes a first transistor and a second transistor,
wherein the selective coupling the first node to the second node includes using the first and second transistors in a low-impedance state, and
wherein the selectively isolating the first node from the second node includes using the first and second transistors in a high-impedance state.

14. The method of claim 13,
wherein the first transistor includes a p-channel transistor having a gate, a source, and a drain, and wherein the first node includes the source of the first transistor, and
wherein the second transistor includes an n-channel transistor having a gate, a source, and a drain, and wherein the first node includes the source of the second transistor.

15. The method of claim 14, including:
receiving an enable signal using a gate of a third transistor: and
selectively coupling the gate of the first transistor to ground using the enable signal.

16. The method of claim 14,
wherein the output of the arbiter circuit is coupled to the gate of the first transistor using a resistor, and
wherein a bulk of the first transistor is coupled to the output of the arbiter circuit.

17. The method of claim 14, wherein the second node includes the drain of the first transistor and the drain of the second transistor.

18. The method of claim 11,
wherein the arbiter circuit includes a fourth transistor and a fifth transistor, each having a gate, a source, and a drain,
wherein the receiving the source voltage includes using the drain of the fourth transistor and the gate of the fifth transistor,
wherein the receiving the input signal includes using the gate of the fourth transistor and the drain of the fifth transistor, and
wherein the providing the higher voltage of the source voltage and the input signal includes using the source of the fourth transistor and the source of the fifth transistor.

19. The method of claim 11, wherein the output of the arbiter circuit is coupled to a control node of the switch using a resistor.

20. The method of claim 19, including a third transistor coupled to the control node of the switch and configured to receive an enable signal and to control the switch using the enable signal.

21. A system comprising:
a switch having a tow-impedance state configured to couple a first node to a second node and a high-impedance state configured to isolate the first node from the second node, the switch including:
a first transistor and a second transistor, each having a tow-impedance state configured to couple the first node to the second node and a high-impedance state configured to isolate the first node from the second node,
wherein the first transistor includes a p-channel transistor having a gate, a source, and a drain, and the second transistor includes an n-channel transistor having a gate, a source, and a drain,
wherein the first node includes the source of the first transistor and the source of the second transistor, and
wherein the second node includes the drain of the first transistor and the drain of the second transistor,
a third transistor configured to receive an enable signal and to selectively couple the gate of the first transistor to ground using the enable signal;
an arbiter circuit configured to receive a source voltage and an input signal and to provide at an output the higher voltage of the source voltage and the input signal, wherein the arbiter circuit includes:
a fourth transistor and a fifth transistor, each having a gate, a source, and a drain,
wherein the drain of the fourth transistor is configured to receive the source voltage and the gate of the fourth transistor is configured to receive the input signal,
wherein the drain of the fifth transistor is configured to receive the input signal and the gate of the fifth transistor is configured to receive the source voltage, and
wherein the source of the fourth transistor is coupled to the source of the fifth transistor and configured to provide the higher voltage of the source voltage and the input signal;
a resistor configured to couple the output of the arbiter circuit to the gate of the first transistor; and
a ground path between a control input of the switch and circuit ground,
wherein a bulk of the first transistor is coupled to the output of the arbiter circuit, and
wherein the arbiter circuit is configured to isolate the input signal from the ground path when the input signal has a lower voltage than the source voltage and when the switch is in the low-impedance state.
